(19) United States
(12) Patent Application Publication
(10) Pub. No.: US 2026/0100708 A1
(43) Pub. Date: Apr. 9, 2026

(54) VOLTAGE LEVEL SHIFTER

(71) Applicant: Winbond Electronics Corp., Taichung City (TW)

(72) Inventor: Chung-Zen Chen, HsinChu (TW)

(73) Assignee: Winbond Electronics Corp., Taichung City (TW)

(21) Appl. No.: 19/263,525

(22) Filed: Jul. 9, 2025

(30) Foreign Application Priority Data
Oct. 8, 2024 (TW) 113138312

(51) Int. Cl. H03K 19/0185

(52) U.S. Cl. CPC H03K 19/018528

(57) ABSTRACT

A voltage level shifter is provided. The voltage level shifter includes a voltage level shift circuit and a boost circuit. The voltage level shift circuit includes a first boost input terminal, a second boost input terminal, a first reference input terminal and a second reference input terminal. The voltage level shift circuit operates between a first voltage and a second voltage. The boost circuit is coupled to the voltage level shift circuit. The boost circuit is configured to pre-charge the first boost input terminal and the second boost input terminal to a third voltage value, and to boost the third voltage value to a fourth voltage value according to pair of differential signals provided to the first reference input terminal and the second reference input terminal.

### CROSS-REFERENCE TO RELATED APPLICATION

This application claims the priority benefit of Taiwan application serial no. 113138312, filed on October 8, 2024. The entirety of the above-mentioned patent application is hereby incorporated by reference herein and made a part of this specification.

### BACKGROUND

### Technical Field

The disclosure relates to an electronic circuit, and in particular to a voltage level shifter.

### Description of Related Art

Generally speaking, electronic products may switch between different working voltage ranges through voltage level shifters, to implement various functions. For example, a memory device includes a voltage level shifter, and performs a shift operation between different voltage values through the voltage level shifter.

However, since a pull-up element and a pull-down element of the conventional voltage level shifter have equivalent driving abilities, in an operation that a voltage signal is switched from a low voltage value to a high voltage value, there is a fierce voltage fighting on an output terminal between the pull-up element and the pull-down element. In this way, the conventional voltage level shifter consumes too much power, thereby reducing the speed of signal transition.

### SUMMARY

An embodiment of the disclosure provides a voltage level shifter, which is capable of reducing the voltage fighting, thereby reducing the power consumption and increasing the speed of signal transition.

A voltage level shifter of the embodiment of the disclosure includes a voltage level shift circuit and a boost circuit. The voltage level shift circuit includes a first boost input terminal, a second boost input terminal, a first reference input terminal and a second reference input terminal. The voltage level shift circuit operates between a first voltage and a second voltage. The boost circuit is coupled to the voltage level shift circuit. The boost circuit is configured to pre-charge the first boost input terminal and the second boost input terminal to a third voltage value, and to boost the third voltage value to a fourth voltage value according to pair of differential signals provided to the first reference input terminal and the second reference input terminal.

Based on the above, the voltage level shifter of the embodiment of the disclosure, by pre-charging multiple boost input terminals of the voltage level shift circuit through the boost circuit, is capable of increasing voltage values on the boost input terminals, thereby reducing the voltage fighting. As such, the voltage level shifter is capable of reducing the power consumption and increasing the speed of signal transition.

### BRIEF DESCRIPTION OF THE DRAWINGS

FIG. 1 is a block diagram of a voltage level shifter according to an embodiment of the disclosure.

FIG. 2 is a circuit diagram of a voltage level shifter according to an embodiment of the disclosure.

FIG. 3 is a schematic diagram of an operation of the voltage level shifter according to the embodiment of FIG. 2 of the disclosure.

### DESCRIPTION OF THE EMBODIMENTS

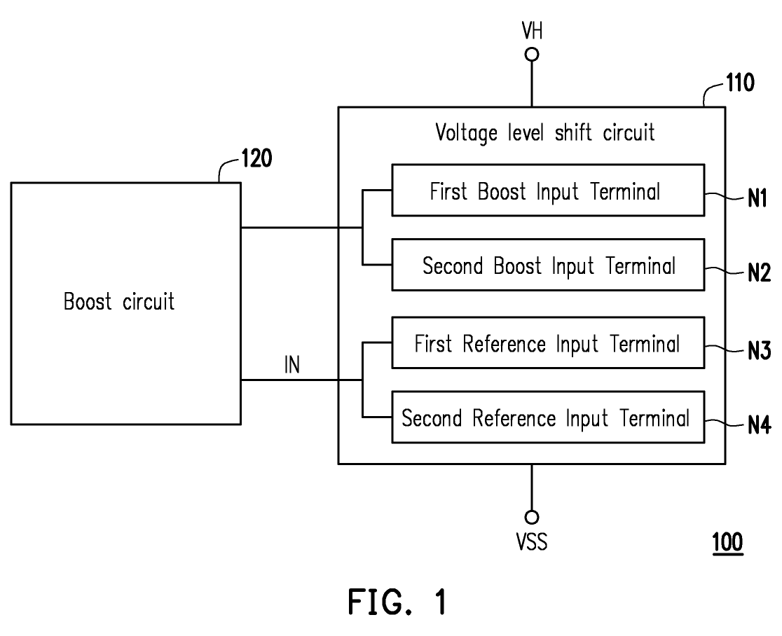

Refer to FIG. 1. A voltage level shifter 100 may be, for example, a voltage level shifter with a high voltage. The voltage level shifter 100 is configured to perform a shift operation between a voltage value of a first voltage VH and a voltage value of a second voltage VSS. The first voltage VH may be, for example, a high-power voltage. The second voltage VSS may be, for example, a low-power voltage. The voltage level shifter 100 may, for example, have a circuit configuration of single-terminal output and differential input.

In the embodiment of FIG. 1, the voltage level shifter 100 includes a voltage level shift circuit 110 and a boost circuit 120. The voltage level shift circuit 110 is coupled to the boost circuit 120. In detail, the voltage level shift circuit 110 operates between the first voltage VH and the second voltage VSS. The voltage level shift circuit 110 includes a first boost input terminal N1, a second boost input terminal N2, a first reference input terminal N3 and a second reference input terminal N4. The first boost input terminal N1 and the second boost input terminal N2 are coupled to the boost circuit 120. The first reference input terminal N3 and the second reference input terminal N4 are coupled to the boost circuit 120, and receive a provided pair of differential signals IN.

In the shift operation, the boost circuit 120 pre-charges the first boost input terminal N1 and the second boost input terminal N2 to a third voltage value. The boost circuit 120 boosts the third voltage value on the first boost input terminal N1 and the second boost input terminal N2 to a fourth voltage value, according to the pair of differential signals IN. The fourth voltage value is greater than the third voltage value.

It is worth mentioning that, by pre-charging multiple boost input terminals N3 to N4 of the voltage level shift circuit 110 through the boost circuit 120, the voltage level shifter 100 is capable of increasing the voltage values on these boost input terminals N3 to N4. Therefore, based on the increased voltage value (i.e., the third voltage value), the driving ability of the pull-up element of the voltage level shifter 100 can be weaken, thereby reducing the voltage fighting. As such, the voltage level shifter 100 is capable of reducing the power consumption and increasing the speed of signal transition, thereby reducing the transient current.

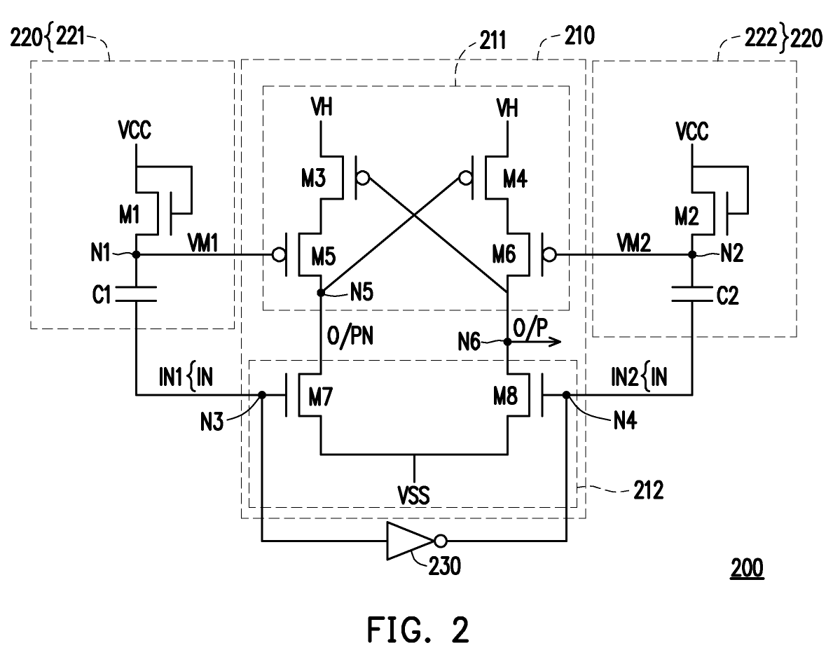

Refer to FIG. 2. A voltage level shifter 200 includes a voltage level shift circuit 210 and a boost circuit 220. The voltage level shift circuit 210 and the boost circuit 220 may be referenced and analogized from the relevant description of the voltage level shifter 100.

In the embodiment of FIG. 2, the boost circuit 220 includes a first boost circuit block 221 and a second boost circuit block 222. The first boost circuit block 221 is coupled to the first boost input terminal N1 and the first reference input terminal N3 of the voltage level shift circuit 210. The first boost circuit block 221 receives a supply voltage VCC. In this embodiment, the supply voltage VCC has the third voltage value.

Specifically, the first boost circuit block 221 includes a first transistor M1 and a first capacitor C1. The first transistor M1 may be, for example, implemented as an n-type metal-oxide-semiconductor field-effect transistor (NMOSFET). In this embodiment, the first transistor M1 may be a native transistor. In other words, a critical voltage value of the first transistor M1 approaches zero. In other embodiments, the first transistor M1 may also be a normal transistor, and the critical voltage value is less than the voltage value of the supply voltage VCC.

In detail, a control terminal (i.e., a gate terminal) and a first terminal (i.e., a first source/drain terminal) of the first transistor M1 are coupled together, and receive the supply voltage VCC. In other words, the first transistor M1 is in a diode-connected state. A second terminal (i.e., a second source/drain terminal) of the first transistor M1 is coupled to the first boost input terminal N1 and a first terminal of the first capacitor C1. A second terminal of the first capacitor C1 is coupled to the first reference input terminal N3.

In this embodiment, the second boost circuit block 222 is coupled to the second boost input terminal N2 and the second reference input terminal N4 of the voltage level shift circuit 210. The second boost circuit block 222 receives the supply voltage VCC.

Specifically, the second boost circuit block 222 includes a second transistor M2 and a second capacitor C2. The second transistor M2 may be, for example, implemented as an NMOSFET. In the embodiment, the second transistor M2 may be a native transistor and has a critical voltage value approaching zero. In other embodiments, the second transistor M2 may also be a normal transistor, and the critical voltage value is less than the voltage value of the supply voltage VCC. The transistors M1 and M2 are both taken as the native transistors in the following description.

In detail, a control terminal (i.e., a gate terminal) and a first terminal (i.e., a first source/drain terminal) of the second transistor M2 are coupled together, and receive the supply voltage VCC. In other words, the second transistor M2 is in a diode-connected state. A second terminal (i.e., a second source/drain terminal) of the second transistor M2 is coupled to the second boost input terminal N2 and a first terminal of the second capacitor C2. A second terminal of the second capacitor C2 is coupled to the second reference input terminal N4.

In this embodiment, the voltage level shift circuit 210 includes a pair of cross-coupled transistors 211 and a pair of differential transistors 212. The pair of cross-coupled transistors 211 are coupled to the pair of differential transistors 212. The pair of cross-coupled transistors 211 have the first boost input terminal N1 to be coupled to the first boost circuit block 221. The pair of cross-coupled transistors 211 have the second boost input terminal N2 to be coupled to the second boost circuit block 222. The pair of cross-coupled transistors 211 receive the first voltage VH.

In detail, the pair of cross-coupled transistors 211 include a third transistor M3, a fourth transistor M4, a fifth transistor M5 and a sixth transistor M6. These transistors M3 to M6 may be, for example, implemented as p-type metal-oxide-semiconductor field-effect transistors (PMOSFET).

In this embodiment, a control terminal (i.e., a gate terminal) of the third transistor M3 is coupled to a node N6. The node N6 serves as an output terminal of the voltage level shifter 200. A first terminal (i.e., a first source/drain terminal) of the third transistor M3 receives the first voltage VH. A second terminal (i.e., a second source/drain terminal) of the third transistor M3 is coupled to a first terminal (i.e., a first source/drain terminal) of the fifth transistor M5. A control terminal (i.e., a gate terminal) of the fifth transistor M5 serves as the first boost input terminal N1. A second terminal (i.e., a second source/drain terminal) of the fifth transistor M5 is coupled to a node N5.

Continuing with the above description, a control terminal (i.e., a gate terminal) of the fourth transistor M4 is coupled to the second terminal (i.e., the second source/drain terminal) of the fifth transistor M5 and the pair of differential transistors 212 at the node N5. A first terminal (i.e., a first source/drain terminal) of the fourth transistor M4 receives the first voltage VH. A second terminal (i.e., a second source/drain terminal) of the fourth transistor M4 is coupled to a first terminal (i.e., a first source/drain terminal) of the sixth transistor M6. A control terminal (i.e., a gate terminal) of the sixth transistor M6 serves as the second boost input terminal N2. A second terminal (i.e., a second source/drain terminal) of the sixth transistor M6 is coupled to the control terminal (i.e., the gate terminal) of the third transistor M3 and the pair of differential transistors 212 at the node N6.

In this embodiment, the pair of differential transistors 212 have the first reference input terminal N1 to be coupled to the first boost circuit block 221. The pair of differential transistors 212 have the second reference input terminal N4 to be coupled to the second boost circuit block 222. The pair of differential transistors 212 receive the second voltage VSS.

In detail, the pair of differential transistors 212 include a seventh transistor M7 and an eighth transistor M8. These transistors M7 to M8 may be, for example, implemented as NMOSFETs. A control terminal (i.e., a gate terminal) of the seventh transistor M7 serves as the first reference input terminal N3. A first terminal (i.e., a first source/drain terminal) of the seventh transistor M7 is coupled to the second terminal (i.e., the second source/drain terminal) of the fifth transistor M5 and the control terminal (i.e., the gate terminal) of the fourth transistor M4 at the node N5. A second terminal (i.e., a second source/drain terminal) of the seventh transistor M7 receives the second voltage VSS.

Continuing with the above description, a control terminal (i.e., a gate terminal) of the eighth transistor M8 serves as the second reference input terminal N4. A first terminal (i.e., a first source/drain terminal) of the eighth transistor M8 is coupled to the control terminal (i.e., the gate terminal) of the third transistor M3 and the second terminal (i.e., the second source/drain terminal) of the sixth transistor M6 at the node N6. A second terminal (i.e., a second source/drain terminal) of the eighth transistor M8 receives the second voltage VSS.

It should be noted that, respective sizes of the first transistor M1 and the second transistor M2 is different from a size of any one of the third transistor M3, the fourth transistor M4, the fifth transistor M5, the sixth transistor M6, the seventh transistor M7 and the eighth transistor M8. For example, compared with other transistors M3 to M8, the first transistor M1 has a shorter channel length, and has a thinner gate oxide. The first transistor M1 and the second transistor M2 may have the same size. As such, a layout area of the boost circuit 220 can be reduced.

In this embodiment, the voltage level shifter 200 further includes a inverter 230. A first terminal (i.e., an input terminal) of the inverter 230 is coupled to the first reference input terminal N3. A second terminal (i.e., an output terminal) of the inverter 230 is coupled to the second reference input terminal N4. In other words, the inverter 230 provides the pair of differential signals IN (i.e., a first differential signal IN1 and a second differential signal IN2) with inversion at the first reference input terminal N3 and the second reference input terminal N4.

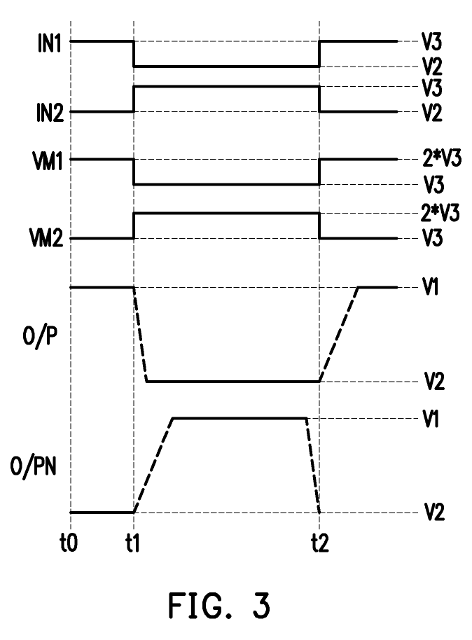

Refer to FIG. 2 and FIG. 3 at the same time. In FIG. 3, the horizontal axis is the operation time of the voltage level shifter 200, and the vertical axis is the voltage value. In this embodiment, the first voltage VH has a first voltage value V1. The second voltage VSS has a second voltage value V2. The supply voltage VCC has a third voltage value V3. The first voltage value V1 is greater than the third voltage value V3 and may be, for example, 10 volts (V). The third voltage value V3 is greater than the second voltage value V2 and may be, for example, 1.8V. The second voltage value V2 may be, for example, a reference ground voltage value.

In the shift operation, the voltage level shifter 200, for example, switches an output voltage O/P from a high voltage value (i.e., the first voltage value V1) to a low voltage value (i.e., the second voltage value V2) at a time t1.

In detail, before the time t1, the fourth transistor M4 is turned on. The third transistor M3 is turned off. The first transistor M1 is turned on to pre-charge the first boost input terminal N1 according to the supply voltage VCC. Since the first transistor M1 is a native transistor, the voltage VM1 on the first boost input terminal N1 is pre-charged to be equal to or substantially equal to the voltage value (i.e., the third voltage value V3) of the supply voltage VCC. In addition, the voltage (i.e., the first differential signal IN1 with the third voltage value V3) on the first reference input terminal N3 is further provided to the first boost input terminal N1 through the first capacitor C1, such that the voltage VM1 has a voltage value that is equal to or substantially equal to twice the third voltage value V3.

Similarly, the voltage VM2 on the second boost input terminal N2 is pre-charged to be equal to or substantially equal to the voltage value (i.e., the third voltage value V3) of the supply voltage VCC through the second transistor M2. In addition, since the second reference input terminal N4 has the second voltage value V2 (i.e., the reference ground voltage value), the voltage VM2 is maintained at the third voltage value V3.

At the time t1, the second differential signal IN2 switches from the second voltage value V2 to the third voltage value V3. The eighth transistor M8 is controlled by the second differential signal IN2, and is turned on, so as to pull down the output voltage O/P at the node N6 to the voltage value (i.e., the second voltage value V2) of the second voltage VSS. The third transistor M3 is controlled by the output voltage O/P at the node N6, and is turned on.

Simultaneously, the voltage (i.e., the second differential signal IN2 with the third voltage value V3) on the fourth reference input terminal N4 is provided to the second boost input terminal N2 through the second capacitor C2, such that the voltage VM2 is pulled up from the third voltage value V3 to twice the third voltage value V3. The sixth transistor M6 is controlled by the voltage VM2 on the second boost input terminal N2, and the ability of pulling up is weaken.

Continuing with the above description, at the time t1, the first differential signal IN1 switches from the third voltage value V3 to the second voltage value V2. The seventh transistor M7 is controlled by the first differential signal IN1, and is turned off. The fifth transistor M5 is controlled by the voltage VM1 on the first boost input terminal N1, and is turned on. The voltage O/PN on the node N5 is pulled up to the voltage value (i.e., the first voltage value V1) of the first voltage VH through the third transistor M3 and the fifth transistor M5, to turn off the fourth transistor M4, and the shift operation ends.

It should be noted that, the voltage VM2 on the second boost input terminal N2 is pre-charged to the voltage value (i.e., the third voltage value V3) of the supply voltage VCC through the second transistor M2, and is further pulled up to twice the third voltage value V3 through the second capacitor C2. Therefore, in the shift operation, the voltage difference between the pull-up element (including, the fourth transistor M4 and the sixth transistor M6) and the pull-down element (including, the eighth transistor M8) of the voltage level shift circuit 210 can be modulated to twice the third voltage value V3, thereby the driving ability of the pull-up element (e.g., the sixth transistor M6) can be weaken, and the voltage fighting is reduced accordingly. As such, the pull-down element is capable of pulling down the output voltage O/P to the second voltage V2 easily and quickly, such that the corresponding voltage O/PN can be quickly pulled up to the first voltage value V1.

In the shift operation, the voltage level shifter 200, for example, switches the output voltage O/P from a low voltage value (e.g., the second voltage value V2) to a high voltage value (e.g., the first voltage value V1) at a time t2. The operations at the time t2 of the voltage level shifter 200 may be referenced and analogized from the relevant description regarding the voltage level shifter 200 at the time t1.

It should be noted that, at the time t2, the voltage VM1 on the first boost input terminal N1 is pre-charged to the voltage value (i.e., the third voltage value V3) of the supply voltage VCC through the first transistor M1, and is further pulled up to twice the third voltage value V3 through the first capacitor C1. Therefore, in the shift operation, the control terminal of the pull-up element (e.g., the fifth transistor M5) of the voltage level shift circuit 210 can be modulated to twice the third voltage value V3, thereby the driving ability of the pull-up element (e.g., the fifth transistor M5) can be weaken. As a result, the voltage fighting is reduced, and the pull-down elements is capable of pulling down the output voltage O/PN to the second voltage V2 easily and quickly, such that the corresponding voltage O/P can be quickly pulled up to the first voltage value V1.

In summary, the voltage level shifter of the embodiment of the disclosure, by pre-charging multiple boost input terminals of the voltage level shift circuit through the boost circuit, is capable of increasing the voltage values on these boost input terminals. Therefore, the driving ability of the pull-up element of the voltage level shift circuit can be weaken, thereby reducing the voltage fighting. As such, the voltage level shifter is capable of reducing the power consumption and increasing the speed of signal transition.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A voltage level shifter, comprising:
a voltage level shift circuit, comprising a first boost input terminal, a second boost input terminal, a first reference input terminal and a second reference input terminal, and operating between a first voltage and a second voltage; and
a boost circuit, coupled to the voltage level shift circuit, and configured to pre-charge the first boost input terminal and the second boost input terminal to a third voltage value, and to boost the third voltage value to a fourth voltage value according to a pair of differential signals provided to the first reference input terminal and the second reference input terminal.

2. The voltage level shifter according to claim 1, wherein the boost circuit comprises:
a first boost circuit block, coupled to the first boost input terminal and the first reference input terminal, and configured to receive a supply voltage; and
a second boost circuit block, coupled to the second boost input terminal and the second reference input terminal, and configured to receive the supply voltage.

3. The voltage level shifter according to claim 2, wherein the supply voltage has the third voltage value.

4. The voltage level shifter according to claim 2, wherein the first boost circuit block comprises:
a first transistor, having a control terminal and a first terminal to receive the supply voltage; and
a first capacitor, having a first terminal coupled to a second terminal of the first transistor and the first boost input terminal, wherein a second terminal of the first capacitor is coupled to the first reference input terminal.

5. The voltage level shifter according to claim 4, wherein the second boost circuit block comprises:
a second transistor, having a control terminal and a first terminal to receive the supply voltage; and
a second capacitor, having a first terminal coupled to a second terminal of the second transistor and the second boost input terminal, wherein a second terminal of the second capacitor is coupled to the second reference input terminal.

6. The voltage level shifter according to claim 5, wherein the voltage level shift circuit comprises:
a pair of cross-coupled transistors, having the first boost input terminal and the second boost input terminal, and configured to receive the first voltage; and
a pair of differential transistors, coupled to the pair of cross-coupled transistors, having the first reference input terminal and the second reference input terminal, and configured to receive the second voltage.

7. The voltage level shifter according to claim 6, wherein the pair of cross-coupled transistors comprise:
a third transistor, having a first terminal to receive the first voltage;
a fourth transistor, having a first terminal to receive the first voltage;
a fifth transistor, having a control terminal serving as the first boost input terminal, wherein a first terminal of the fifth transistor is coupled to a second terminal of the third transistor, and a second terminal of the fifth transistor is coupled to a control terminal of the fourth transistor and the pair of differential transistors; and
a sixth transistor, having a control terminal serving as the second boost input terminal, wherein a first terminal of the sixth transistor is coupled to a second terminal of the fourth transistor, and a second terminal of the sixth transistor is coupled to a control terminal of the third transistor and the pair of differential transistors.

8. The voltage level shifter according to claim 7, wherein the pair of differential transistors comprises:
a seventh transistor, having a control terminal serving as the first reference input terminal, wherein a first terminal of the seventh transistor is coupled to the second terminal of the fifth transistor and the control terminal of the fourth transistor, and a second terminal of the seventh transistor is configured to receive the second voltage; and
an eighth transistor, having a control terminal serving as the second reference input terminal, wherein a first terminal of the eighth transistor is coupled to the second terminal of the sixth transistor and the control terminal of the third transistor, and a second terminal of the eighth transistor is configured to receive the second voltage.

9. The voltage level shifter according to claim 8, wherein respective sizes of the first transistor and the second transistor is different from a size of any one of the third transistor, the fourth transistor, the fifth transistor, the sixth transistor, the seventh transistor and the eighth transistor.

10. The voltage level shifter according to claim 1, further comprising:
a inverter, having a first terminal coupled to the first reference input terminal, wherein a second terminal of the inverter is coupled to the second reference input terminal.
